(19) United States
(12) Patent Application Publication
(10) Pub. No.: US 2010/0167530 A1
(43) Pub. Date: Jul. 1, 2010

(54) METHOD FOR FORMING METAL LINE OF SEMICONDUCTOR DEVICE

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/643,908

(22) Filed: Dec. 21, 2009

(30) Foreign Application Priority Data
Dec. 29, 2008 (KR) 10-2008-0136090

(51) Int. Cl. H01L 21/768; H01L 21/306; H01L 21/311

(52) U.S. Cl. 438/653; 438/700; 257/E21.584; 257/E21.577; 257/E21.585; 257/E21.249; 257/E21.228

(57) ABSTRACT

Disclosed is a method for forming a metal line of a semiconductor device. The method includes forming a first photoresist pattern on at least one interlayer dielectric provided on a semiconductor substrate, etching the interlayer dielectric using the first photoresist pattern to form a trench, removing the first photoresist pattern by ashing, and primarily removing residues left in the trench using a first cleaning solution comprising TMH, H₂O₂ and H₂. Accordingly, copper metal lines with a great thickness of not less than 3 to 5 um can be formed, while preventing generation of voids in the process of forming the diffusion barrier and metal lines, thus advantageously improving yield and reliability of products.

The present application claims priority under 35 U.S.C. §119 to Korean Patent Application No. 10-2008-0136090 (filed on Dec. 29, 2008), which is hereby incorporated by reference in its entirety.

### BACKGROUND

In accordance with the development of semiconductor techniques, semiconductor devices utilized in a variety of applications are increasingly developed. Semiconductor devices were used for computer chips or electric circuits, while they are commonly applied to various fields including automobiles, aircraft, mobile communications, etc.

Semiconductor devices having metal lines made of copper (Cu) achieve better RC delay than metal lines made of aluminum (Al). Accordingly, semiconductor devices having copper metal lines are increasingly applied to analog devices and research associated therewith is currently underway.

A damascene process is a method generally used to form copper metal lines in back end of line (BEOL) processes. In order to increase a sheet resistance (Rs), it is necessary to deposit copper to a thickness of 3 to 5 μm. This thick layer of copper causes an increase in thickness of photoresists to pattern trenches and vias which require a large depth and production of a great amount of polymers in reactive ion etching (RIE). In subsequent ashing and removing processes, polymer residues left around the trenches are removed and a diffusion barrier and copper lines are then formed. In such a damascene process, the amount of polymer produced increases as the thickness of copper deposited increases. For this reason, disadvantageously, polymer and particles left under trenches cannot be completely removed by general ashing and removing processes.

FIGS. 1A and 1B are views illustrating a diffusion barrier and copper metal lines formed by a method for forming metal lines of a semiconductor device.

FIG. 1A is an image illustrating a diffusion barrier and copper metal lines formed after forming trenches and vias with a thickness of 3 to 5 μm in a copper damascene process. FIG. 1B is an image illustrating copper metal lines formed in that time. From images taken after ashing and removing processes, residues left behind are invisible to the naked eye. Accordingly, it is necessary to observe images, such as FIGS. 1A and 1B, taken after forming diffusion barriers and metal lines.

As illustrated in FIG. 1A, a void 10 may be generated in the diffusion barrier formed by a method. This void 10 causes production of undesired metal line portions 20. The production of the void 10 is due to incomplete removal of polymer and particles left behind after formation of the trench. These residues cause rapid deterioration in adhesion due to thermal expansion, when the diffusion barrier is formed at about 300 to 500. Similarly, a copper metal is not smoothly deposited along the void 10 under these conditions.

As a result, residues such as polymer and particles left behind after forming the trench cannot be completely removed, thereby causing defects in the formation of diffusion barrier and forming voids. Furthermore, the voids of diffusion barrier lead to defects of copper metal lines, disadvantageously causing deterioration in characteristics of semiconductor device products.

### SUMMARY

Embodiments relate to a method for manufacturing semiconductor devices, particularly, a method for forming metal lines of semiconductor devices utilizing a damascene process.

Embodiments relate to a method for forming metal lines of a semiconductor device that maximizes removal of residues such as polymer and particles left around a trench patterned to form metal lines.

In accordance with embodiments, a method for forming a metal line of a semiconductor device can include at least one of the following: forming a first photoresist pattern on and/or over at least one interlayer dielectric provided on a semiconductor substrate; etching the interlayer dielectric using the first photoresist pattern to form a trench; removing the first photoresist pattern by ashing; and primarily removing residues left in the trench using a first cleaning solution comprising TMH, H₂O₂ and H₂.

In accordance with embodiments, a method can include at least one of the following: forming an interlayer dielectric over a semiconductor substrate; forming a trench in the interlayer dielectric layer by etching the interlayer dielectric; performing a first cleaning process to remove residues in the trench after forming the trench; and then performing a second cleaning process to remove residues in the trench after performing the first cleaning process.

In accordance with embodiments, a method can include at least one of the following: forming an interlayer dielectric over a semiconductor substrate; forming a trench in the interlayer dielectric layer by etching the interlayer dielectric; performing a first cleaning process to remove residues in the trench after forming the trench; performing a second cleaning process to remove residues in the trench after performing the first cleaning process; forming a via hole by etching the interlayer dielectric using the second photoresist pattern; performing a third cleaning process to remove residues in the via hole after forming the via hole; forming a diffusion barrier over the trench and the via hole; and then forming a metal line in the trench and the via hole and over the diffusion barrier.

### DRAWINGS

FIGS. 1A and 1B illustrate a method of forming a diffusion barrier and copper metal lines of a semiconductor device.

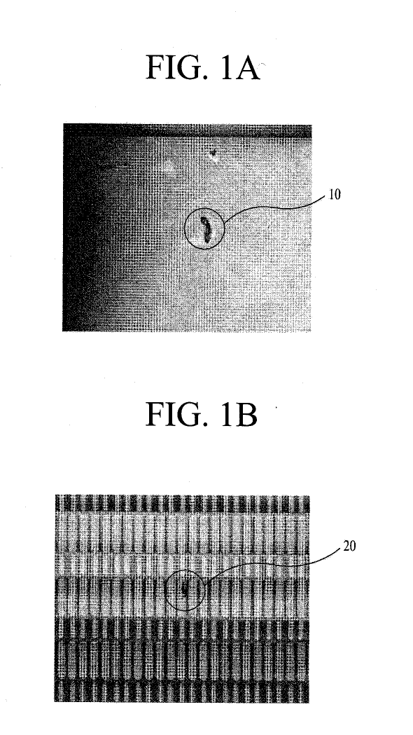

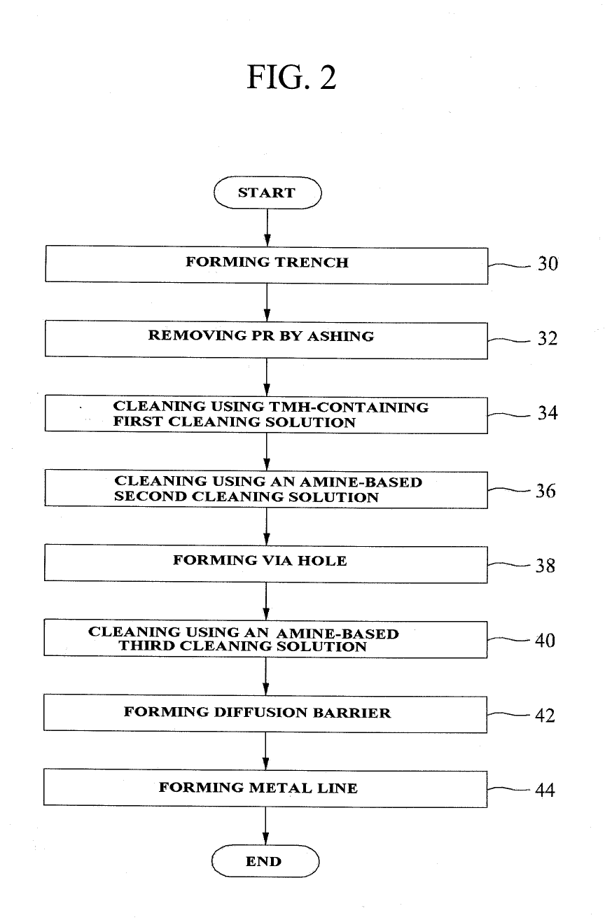

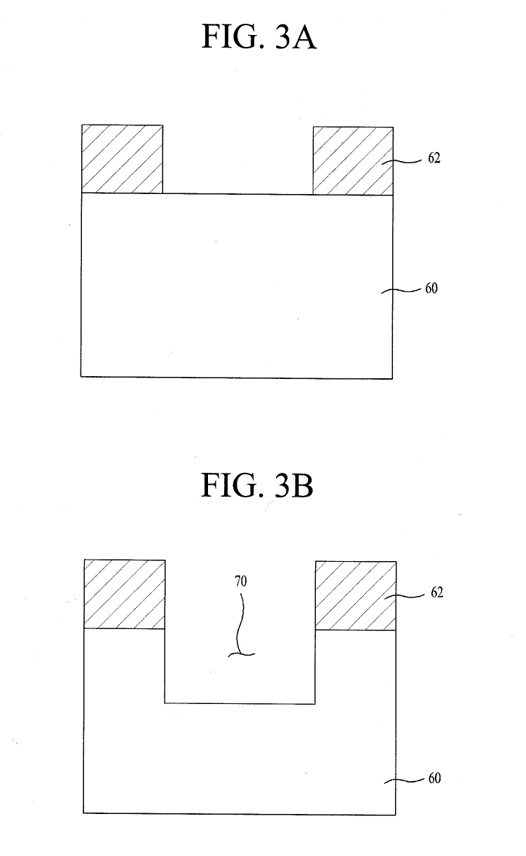

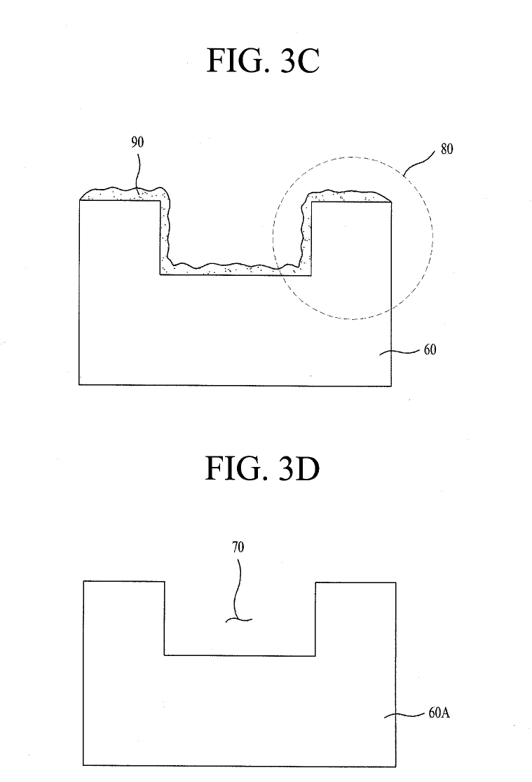

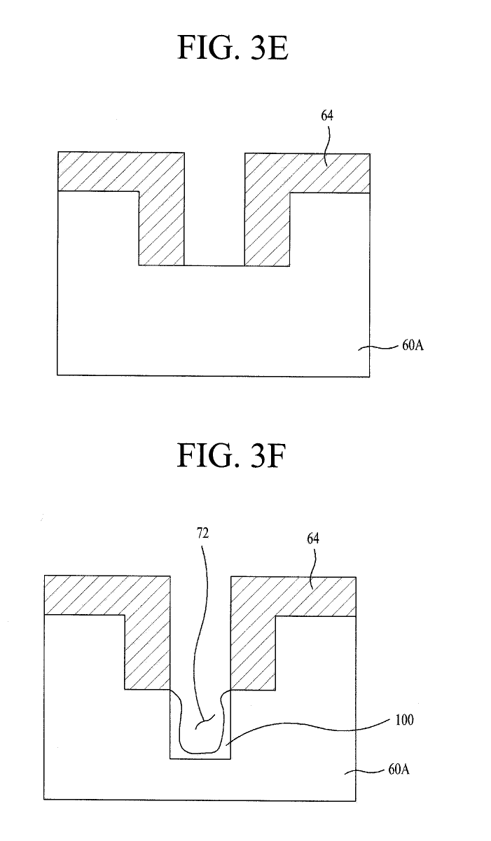

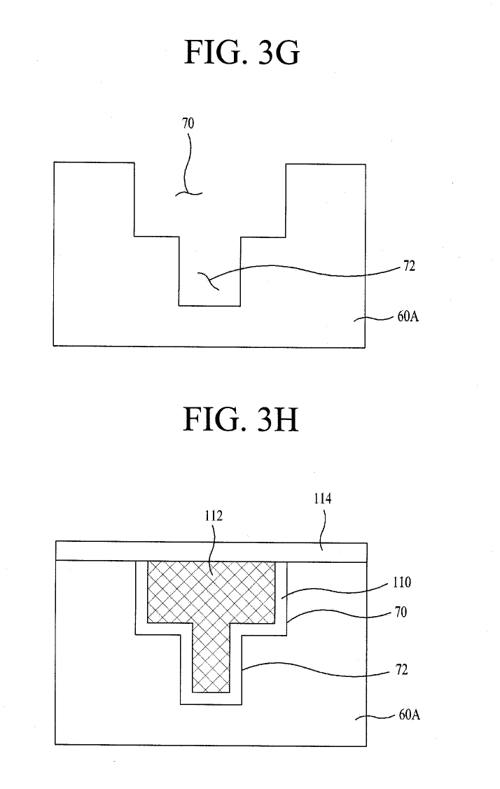

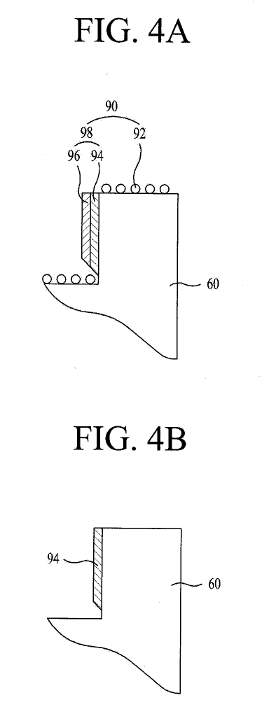

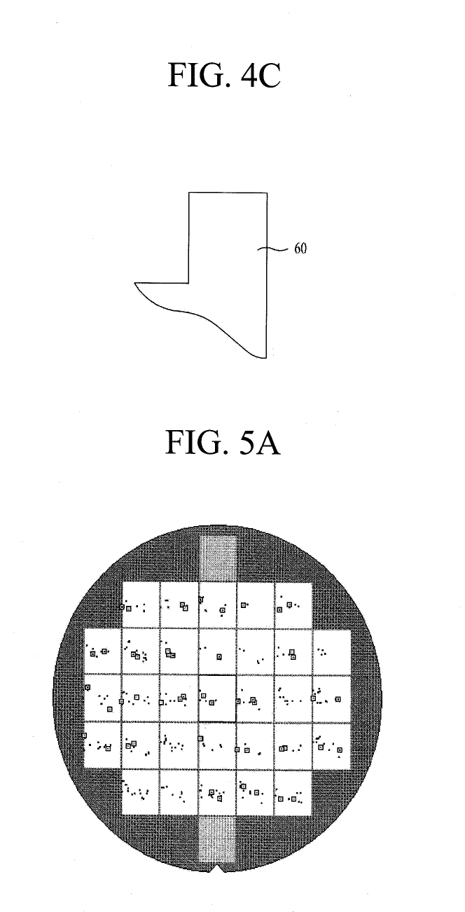

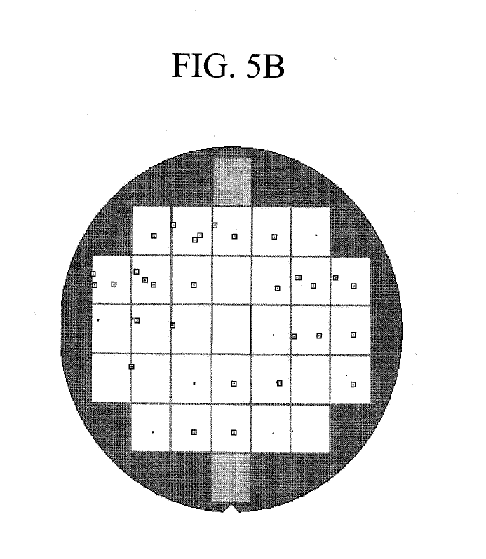

Example FIGS. 2 to 4 illustrate a method for forming metal lines of a semiconductor device, in accordance with embodiments.

Example FIGS. 5A and 5B illustrate wafer defect monitoring results, in accordance with embodiments.

### DESCRIPTION

Hereinafter, a method for forming metal lines of a semiconductor device in accordance with embodiments will be described with reference to the annexed drawings.

As illustrated in example FIGS. 2 to 3, a method for forming metal lines of a semiconductor device includes forming a trench 70 (Step 30). For example, a lower structure (not shown) is formed on and/or over a semiconductor substrate and an interlayer dielectric film 60 is formed thereon and/or thereover, as illustrated in example FIG. 3A.

The interlayer dielectric film 60 may be a laminate comprising a plurality of dielectric films. Then, as shown in FIG. 3B, a first photoresist pattern 62 is formed on the interlayer dielectric film 60 by a photolithographic process. Then, an interlayer dielectric film 60 is etched by a reactive ion etching process using a gas such as CFx and the first photoresist pattern 62 to form a trench 70.

As illustrated in example FIG. 3C, after step 30, the first photoresist pattern 62 is removed by ashing (step 32). The ashing is a method for burning a photoresist using oxygen (O₂) gas.

As illustrated in example FIG. 3C, in the process of forming the trench 70 residues 90 may be formed around the trench 70, i.e., on and/or over the sidewalls and bottommost surface of trench 70 and also on and/or over the interlayer dielectric film 60. The residues 90 include polymer, particles and inherent residues of the photoresist, as reaction products of the gas (such as CFₓ) used for RIE and the photoresist. The trench 70 should be deepened as a metal line 112 is thickened. Accordingly, the first photoresist pattern 62 is inevitably thickened. During etching the interlayer dielectric film 60 to form the trench 70, the sidewalls of the etched interlayer dielectric film 60 may be continuously etched. Accordingly, artificially generated polymers may by adhered to the etched sidewalls and protect the same. Eventually, for various reasons, residues 90 are present around the trench 70.

As illustrated in example FIG. 3D, after performing step 36 the trench 70 from which the residues 90 are completely removed is obtained.

As illustrated in example FIG. 3E, after completely removing the residues from the trench 70, a via hole 72 is formed (Step 38). For example, a secondary photoresist pattern 64 is formed on and/or over an interlayer dielectric 60A provided with the trench 70.

As illustrated in example FIG. 3F, an interlayer dielectric 60A is then etched by a process such as RIE using the secondary photoresist pattern 64 to form a via hole 72. Then, the secondary photoresist pattern 64 is removed by ashing.

As illustrated in example FIG. 3G, after forming the via hole 72, residues 100 may remain inside the via hole 72. Accordingly, prior to formation of the diffusion barrier 110, the residues 100 left inside the via hole 72 are removed using an amine-based third cleaning solution (Step 40). Accordingly, a structure including the via hole 72 and the trench 70, from which the residues 100 are removed is completed.

After step 40, a diffusion barrier 110 is formed in the trench 70 and the via hole 72 (Step 42). The diffusion barrier 110 serves to prevent a metal line 112 formed in the following process from diffusing into the interlayer dielectric 60A.

After step 42, a metal layer is embedded in the trench 70 and the via hole 72 on and/or over the diffusion barrier 110 to form the metal line (Step 44). For example, a copper (Cu)-seeded metal film is deposited on the trench 70 and the via hole 72 by physical vapor deposition (PVD) or chemical vapor deposition (CVD), and the resulting structure is dipped in an electrolytic solution to form the metal layer to a great thickness to the upper part of the interlayer dielectric 60A, while embedding the trench 70 and the via hole 72. Then, the metal layer is polished by chemical mechanical polishing (CMP) until the upper surface of the interlayer dielectric 60A is exposed, to complete formation of the metal line 112.

As illustrated in example FIG. 3H, a diffusion barrier 114 is then formed on and/or over the metal line 112 and the interlayer dielectric 60A. The metal line 112 and the diffusion barrier 114 may be made of a metal, such as titanium (Ti)/titanium nitride (TiN) or tantalum (Ta)/tantalum nitride (TaN). The most important factor, the diffusion barrier 114 to form the copper metal line 112 should be simultaneously carried out with a process for forming the copper metal line 112. This is the reason that delay time is shortened, since copper is readily oxidized into CuO.

As mentioned above, step 34, removal of the residues 90 using the first cleaning solution, may be carried out after the formation of the trench 70 and prior to the formation of the via hole 72. In addition, the present invention is more useful, as the metal line 112 is thickened. This is the reason that the first photoresist pattern 62 is thickened and the amount of residues 90 including polymer and particles produced around the trench 70 increases, as the metal line 112 becomes thicker. For example, the metal line 112 may have a thickness of at least 3 to 5 μm.

Example FIGS. 4A to 4C are partial sectional process views illustrating a process for removing the residues 90 from the part 80 shown in example FIG. 3C.

As illustrated in example FIG. 4A, after step 32, residues 90 left in the trench 70 are removed using a first cleaning solution composed of trimethylammoniumhydroxide (TMH), H₂O₂ and H₂O, as shown in FIG. 4B (Step 34). In accordance with embodiments, the composition of TMH, H₂O₂ and H₂ may be 1:2 to 5:10 to 40. In addition, the removal of the residues 90 using the first cleaning solution may be carried out for 5 to 10 minutes. The removal of the residues 90 using the first cleaning solution may be carried out in a single or batch manner. The single manner refers to a method for individually cleaning a single wafer. The batch manner refers to a method for simultaneously cleaning a plurality of wafers.

In step 34, particles 92 and polymer 96 can be removed from the residues 90 illustrated in example FIG. 4A using the first cleaning solution, as illustrated in example FIG. 4B. The residual polymer 98 left on and/or over the sidewall of the trench 70 includes a hard outer layer 96 and a soft inner layer 94. The first cleaning solution serves to remove not only the particles 92, but also the hard outer layer 96 of the polymer 98.

After step 34, residues 90, in particular, particles 92 and the hard outer layer 96 of the polymer 98 are primarily removed using the first cleaning solution, and remaining residues 94, in particular, the soft inner layer 94 of the polymer 98 are completely removed using a second cleaning solution, e.g., an amine solvent, as illustrated in example FIG. 4C (Step 36). As a result, both the hard outer layer 96 and the soft inner layer 94 of the polymer 98 can be removed and secondary contamination of particles can be thus prevented.

In addition, the polymer left in the trench 70 and on and/or over the interlayer dielectric film 60 as well as the residues of the photoresist can be removed by the primary and second cleaning solutions. In particular, the amine-solvent can be removed by melting the photoresist and polymer.

Ashing to remove not only the first photoresist pattern 62, but also the residues of the photoresist, included in the residues 90, left after removing the first photoresist pattern 62 may be carried out. The ashing may be carried out prior to removal of the residues using the first cleaning solution. That is, the ashing may be carried out immediately after removal of the first photoresist pattern 62.

Example FIGS. 5A and 5B are images illustrating wafer defect monitoring results. As illustrated in example FIG. 5A, the wafer manufactured by a general method for forming a metal line of semiconductor devices has many defects. As illustrated in example FIG. 5B, on the other hand, the wafer manufactured by the method for forming a metal line of semiconductor devices in accordance with embodiments is free of voids, resulting in a reduction in overall defects.

The method for forming a metal line of semiconductor devices in accordance with embodiments may be applied to remove residues left behind after forming the trench, although the damascene process is different from those shown in process sectional views of example FIGS. 3A to 3H. Meaning, embodiments are not limited to those illustrated in the process sectional views of example FIGS. 3A to 3H.

As apparent from the fore-going, in accordance with embodiments, the method for forming metal lines of semiconductor devices, particles and the hard outer layer of the polymer among the residues left behind around the trench after forming the trench are removed using a TMH-containing cleaning solution and the soft inner layer of the polymer is then completely removed using an amine-based cleaning solution. For this reason, copper metal lines with a great thickness of not less than 3 to 5 um can be formed, while also preventing generation of voids in the process of forming the diffusion barrier and metal lines. Accordingly, yield is enhanced as well as product reliability.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a first photoresist pattern over at least one interlayer dielectric provided over a semiconductor substrate;
etching the interlayer dielectric using the first photoresist pattern to form a trench;
removing the first photoresist pattern by performing an ashing process; and then
performing a primary cleaning process removing residues left in the trench using a first cleaning solution comprising TMH, H₂O₂ and H₂.

2. The method of claim 1, further comprising:
performing a secondary cleaning process removing residues left behind after performing the primary cleaning process using a second solution comprising an amine-based compound.

3. The method of claim 1, wherein the ashing process is performed prior to performing the primary cleaning process.

4. The method of claim 1, wherein the first cleaning solution has a ratio of TMH, H₂O₂ and H₂O of 1:2 to 5:10 to 40.

5. The method of claim 4, wherein performing the first cleaning process is carried out for 5 to 10 minutes.

6. The method of claim 1, further comprising:
forming a second photoresist pattern over the interlayer dielectric including the trench;
etching the interlayer dielectric using the second photoresist pattern to form a via hole;
removing the second photoresist pattern;
forming a diffusion barrier over the trench and the via hole; and
embedding a metal layer in the trench and the via hole and over the diffusion barrier to form a metal line.

7. The method of claim 6, wherein performing the first cleaning process is carried out prior to forming the via hole.

8. The method of claim 6, further comprising:
performing a tertiary cleaning process prior to forming the diffusion barrier to remove residues left in the via hole using a third cleaning solution comprising an amine-based compound.

9. The method of claim 6, wherein the metal line has a thickness not less than 3 μm to 5 μm.

10. The method of claim 1, wherein polymer produced during formation of the trench is used for the formation of the trench.

11. The method of claim 1, wherein the residues are removed in a batch manner using the first cleaning solution.

12. The method of claim 2, wherein particles and polymer are removed from the residues using the first cleaning solution.

13. A method comprising:
forming an interlayer dielectric over a semiconductor substrate
forming a trench in the interlayer dielectric layer by etching the interlayer dielectric;
performing a first cleaning process to remove residues in the trench after forming the trench; and then
performing a second cleaning process to remove residues in the trench after performing the first cleaning process.

14. The method of claim 13, wherein the first cleaning process uses a first cleaning solution comprising TMH, H₂O₂ and H₂.

15. The method of claim 14, wherein the first cleaning solution has a ratio of TMH, H₂O₂ and H₂O of 1:2 to 5:10 to 40.

16. The method of claim 13, wherein the second cleaning process uses a second cleaning solution comprising an amine-based compound.

17. A method comprising:
forming an interlayer dielectric over a semiconductor substrate
forming a trench in the interlayer dielectric layer by etching the interlayer dielectric;
performing a first cleaning process to remove residues in the trench after forming the trench;
performing a second cleaning process to remove residues in the trench after performing the first cleaning process;
forming a via hole by etching the interlayer dielectric using the second photoresist pattern;
performing a third cleaning process to remove residues in the via hole after forming the via hole;
forming a diffusion barrier over the trench and the via hole; and then
forming a metal line in the trench and the via hole and over the diffusion barrier.

18. The method of claim 17, wherein the first cleaning process uses a first cleaning solution comprising TMH, H₂O₂ and H₂.

19. The method of claim 17, wherein the second cleaning process uses a second cleaning solution comprising an amine-based compound.

20. The method of claim 17, wherein the third cleaning process uses a third cleaning solution comprising an amine-based compound.
